(19) United States
(12) Patent Application Publication
(10) Pub. No.: US 2008/0157399 A1
(43) Pub. Date: Jul. 3, 2008

(54) PMD LAYER OF SEMICONDUCTOR DEVICE

(76) Inventor: Kyung-Min Park, Seoul (KR)

Correspondence Address: SHERR & NOURSE, PLLC, 620 HERNDON PARKWAY, SUITE 200, HERNDON, VA, 20170, US

(21) Appl. No.: 11/870,855

(22) Filed: Oct. 11, 2007

(30) Foreign Application Priority Data
Dec. 28, 2006 (KR) 10-2006-0135962

(51) Int. Cl. H01L 23/48; H01L 21/441; H01L 21/469

(52) U.S. Cl. 257/784; 438/667; 438/763; 257/E23.01; 257/E21.487; 257/E21.495

(57) ABSTRACT

Embodiments relate to forming a pre-metal dielectric (PMD) layer. According to embodiments, the method may include depositing material of which the pre-metal dielectric layer is made on a semiconductor substrate through a chemical vapor deposition (CVD) process employing a high frequency (HF) power in a range from about 2550 mW to about 2650 mW; and polishing the material to form the pre-metal dielectric layer.

The present application claims priority under 35 U.S.C. 119 and 35 U.S.C. 365 to Korean Patent Application No. 10-2006-0135962 (filed on Dec. 28, 2006), which is hereby incorporated by reference in its entirety.

### FIELD OF THE INVENTION

The present invention relates to a semiconductor device; and, more particularly, to a semiconductor, a method of forming a semiconductor, and a method of forming a pre-metal dielectric (PMD) layer of a semiconductor device.

### BACKGROUND

To form a metal wiring of a semiconductor device, a contact electrode for connecting a lower metal wiring and an upper metal wiring may be formed. The contact electrode may be formed on a pre-metal dielectric (PMD) layer formed from, for example, borophosphosilicate glass (BPSG) material.

A related art process for forming metal wiring is described below with reference to the drawings.

Referring to FIG. 1A, PMD layer 102 may be formed on semiconductor substrate 100. PMD layer 102 may be formed by forming BPSG material on semiconductor substrate 100 by a chemical vapor deposition (CVD) method and polishing the BPSG material by a chemical mechanical polishing (CMP) process.

The CVD process may be performed by using an etch gas of O₂ and Ar, a low frequency (LF) power of 3000 mW and a high frequency (HF) power of 2800 mW.

Referring to FIG. 1B, PMD layer 102 may be selectively etched by photolithography and etch processes, thus forming contact hole 104. Barrier metal layer 106 may be deposited on PMD layer 102 including contact hole 104. Barrier metal layer 106 may be formed by consecutively depositing Ti and TiN.

Though not shown, before contact hole 104 may be formed in PMD layer 102, an anti-reflective coating layer formed of SiH₄ may be formed on PMD layer 102.

Referring to FIG. 1C, a metal layer, for example, a Ti layer may be deposited on barrier metal layer 106 and may gap fill contact hole 104. The Ti layer and barrier metal layer 106 over PMD layer 102 may be sequentially polished by a CMP process, and may form tungsten plug 104a within contact hole 104.

Referring to FIG. 1D, a metal layer may be deposited on the resulting surface by a CVD method. The metal layer may include aluminum (Al). Ti and TiN may be consecutively deposited on or below the Al layer.

The Al metal layer may be selectively patterned through photolithography and etch processes, so that metal wiring 108 electrically connected to semiconductor substrate 100 through tungsten plug 104a may be formed.

However, in the related art metal wiring formation process, adhesion of a PMD layer interface in which the contact hole formed by a CVD method may be formed may be weak and some portions of PMD layer may be ripped out in subsequent processes. Accordingly, there may be a problem in that some materials of PMD layer may drop to a semiconductor device, for example, a pixel region of a CMOS image sensor (CIS), degrading the characteristics of the device.

Further, in the related art metal wiring formation process, stress may be directly applied to PMD layer in the process of polishing PMD layer. Thus, there may be a problem in that some materials of PMD layer drop to a semiconductor device, for example, a pixel region of a CIS, or an overlay mark, degrading the characteristics of the device.

### SUMMARY

Embodiments relate to a semiconductor and a method of forming a semiconductor. Embodiments relate to a method of forming a pre-metal dielectric (PMD) layer of a semiconductor device.

Embodiments relate to a method of forming a PMD layer of a semiconductor device, in which PMD layer may be formed by controlling HF power, which may improve a uniformity of PMD layer and minimizing circle defects.

Embodiments relate to a method of forming a PMD layer of a semiconductor device, in which stress applied to an oxide layer for PMD layer may be reduced and the occurrence of circle defects may be minimized in such a manner that the oxide layer for PMD layer may be formed through controlled HF power, a cap oxide layer may be formed and then polished by a CMP process, thus forming PMD layer.

According to embodiments, a method of forming a pre-metal dielectric (PMD) layer may include depositing material of which the pre-metal dielectric layer may be made on a semiconductor substrate through a chemical vapor deposition (CVD) process employing a high frequency (HF) power in a range from about 2550 mW to about 2650 mW; and polishing the material to form the pre-metal dielectric layer.

According to embodiments, a method of forming a pre-metal dielectric (PMD) layer may include forming an oxide layer on a semiconductor substrate; forming a cap oxide layer on the oxide layer; and polishing the cap oxide layer to form the pre-metal dielectric layer including the oxide layer and the polished cap oxide layer.

According to embodiments, a method of forming a semiconductor device on a semiconductor substrate may include (a) forming a pre-metal dielectric (PMD) layer on the semiconductor substrate through a chemical vapor deposition (CVD) process; (b) selectively etching the pre-metal dielectric layer to form a contact hole and depositing a barrier metal layer on the pre-metal dielectric layer including the contact hole; (c) forming a contact plug within the contact hole; and (d) forming, on the semiconductor substrate on which the contact plug may be formed, a metal wiring electrically connected to the semiconductor substrate through the contact plug.

According to embodiments, a semiconductor device may include a pre-metal dielectric (PMD) layer formed on a semiconductor substrate through a chemical vapor deposition (CVD) process; a contact hole formed by selectively etching the pre-metal dielectric layer; a barrier metal layer deposited on the pre-metal dielectric layer; a contact plug formed within the contact hole; and a metal wiring formed on the semiconductor substrate on which the contact plug may be formed and electrically connected to the semiconductor substrate through the contact plug.

### DRAWINGS

FIGS. 1A to 1D are cross-sectional drawings illustrating a metal wiring formation process with respect to a related art PMD layer.

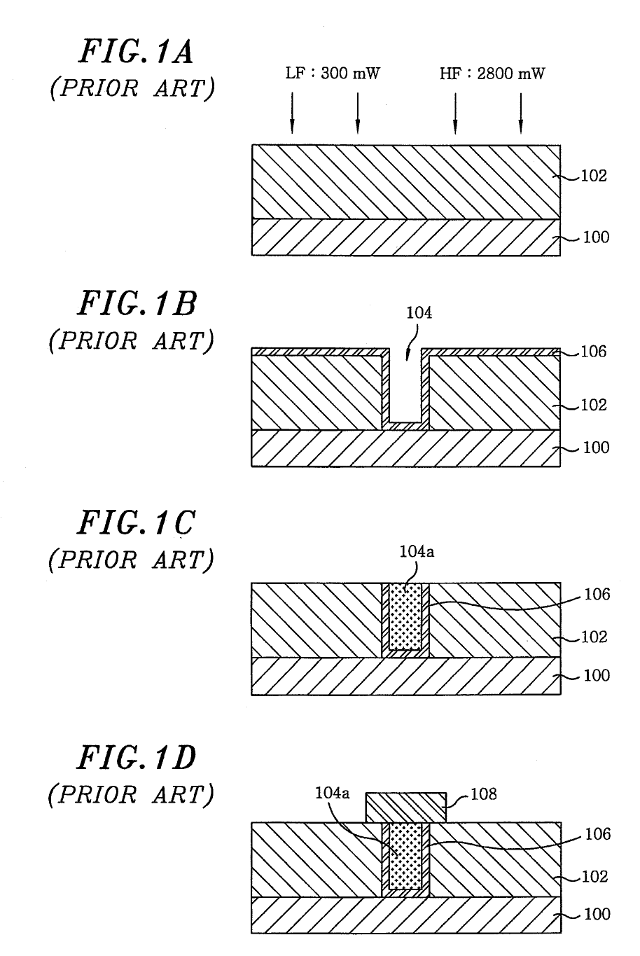

FIG. 2 is a flowchart illustrating a PMD metal wiring formation process according to embodiments.

FIG. 3 is a SEM photograph showing a process condition-based circle defects in FIG. 2.

FIGS. 4A to 4D are cross-sectional drawings illustrating a PMD metal wiring formation process according to embodiments.

### DESCRIPTION

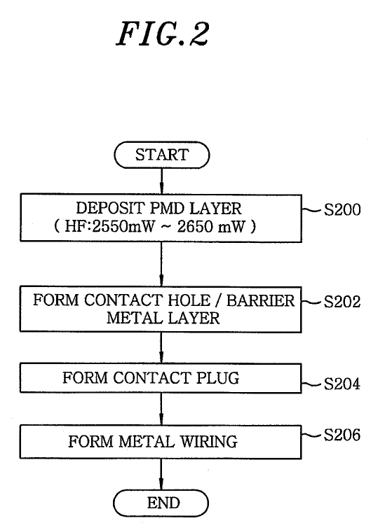

Referring to FIG. 2, PMD layer may be formed on a semiconductor substrate in step S200. PMD layer may be formed by forming BPSG material on the semiconductor substrate, for example by a CVD method, and then polishing the BPSG material, for example by a CMP process. In embodiments, the CVD process may be performed by using an etch gas of O₂ and Ar, an LF power of 3000 mW and an HF power of 2550 to 2650 mW. In the CVD process, HF power may be 2600 mW in order to improve the uniformity of PMD layer.

PMD layer may then be selectively etched by photolithography and etch processes, which may form a contact hole. A barrier metal layer may be deposited on PMD layer including the contact hole in step S202.

In embodiments, before the contact hole is formed in PMD layer, an anti-reflective coating layer formed of SiH₄ may be formed on PMD layer.

Thereafter, a metal layer, for example, a Ti layer, may be deposited on the barrier metal layer and may gap fill the contact hole. The Ti layer and the barrier metal layer over PMD layer may be sequentially polished by a CMP process, thus forming a tungsten plug, that is, a contact plug within the contact hole in step S204.

A metal layer may be deposited on the resulting surface, for example by a CVD method. The metal layer may include aluminum (Al). Ti and TiN may be consecutively deposited on or below the Al layer. The metal layer may be selectively patterned through photolithography and etch processes, thus forming a metal wiring electrically connected to the semiconductor substrate through the tungsten plug in step S206.

As described above, in embodiments, PMD layer may be formed through controlled HF power. From the following table 1, it may be seen that a uniformity of PMD layer may be improved. Thus, some of PMD layer may be prevented from being ripped out in subsequent processes.

TABLE 1

| | | Process | Process | Related art |
|---|---|---|---|---|
| | | Condition 1 | Condition 2 | Process Condition |
| Gas | SiH₄ | 65 | 90 | 90 |
| | O₂ | 126 | 126 | 126 |
| | Ar | 180 | 240 | 240 |
| Power (mW) | LF | 2800 | 3000 | 3000 |
| | HF | 1300 | 2600 | 2800 |

| | | | |
|---|---|---|---|
| Uniformity | 2.84 | 1.95 | 2.7 |

As may be seen from Table 1, in the event that PMD layer is formed on the semiconductor substrate by controlling the HF power as in process condition 2, the uniformity of PMD layer may be improved. A phenomenon in which PMD layer may be ripped out in subsequent processes, that is, a phenomenon in which circle defects occur, may be prevented.

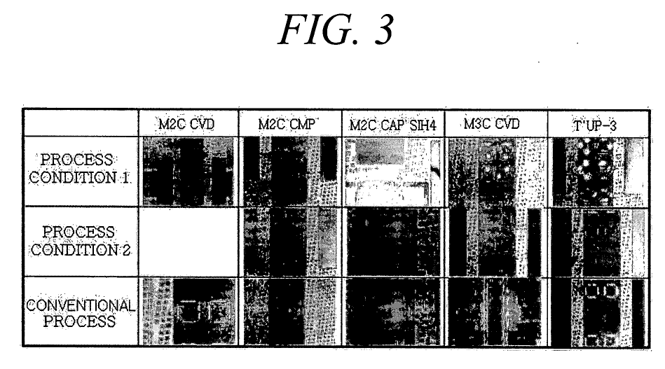

In embodiments, if the condition is applied to the CIS process, circle defects may be generated at the overlayer mark portion in the M3C CVD process step of the process condition 1, but may not occur in the TUP-3 step of the process condition 2, as may be seen from FIG. 3. Further, in the related art process condition, circle defects may be generated in the 3C CVD process step, but may not be generated in the TUP-3 process.

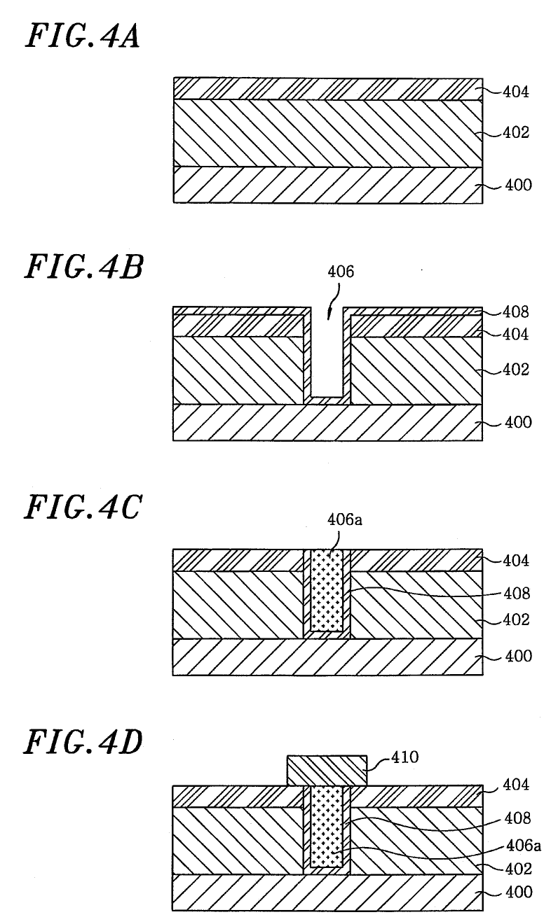

FIGS. 4A to 4D are cross-sectional drawings illustrating a metal wiring formation process, according to embodiments.

Referring to FIG. 4A, oxide layer 402 for a PMD layer may be formed on semiconductor substrate 400. Oxide layer 402 for PMD layer may be formed from BPSG material by a CVD method. In embodiments, the CVD process may be performed by using an etch gas of SiH₄, O₂, and Ar, an LF power of 3000 mW and an HF power of 2550 to 2650 mW. In the CVD process, HF power may be 2600 mW to improve the uniformity of oxide layer 402 for PMD layer. Oxide layer 402 may be formed to have a thickness of approximately 5500 Å to 6500 Å.

Cap oxide layer 404 may be formed to a thickness of approximately 4500 to 5500 Å on oxide layer 402 for PMD layer. The cap oxide layer may be formed from a tetraethyl orthosilicate (TEOS) layer.

Cap oxide layer 404 may be polished by a CMP process, thus forming a PMD layer comprising oxide layer 402 and polished cap oxide layer 404. In embodiments, cap oxide layer 404 may be polished to have a thickness of 2000 Å to 2500 Å.

According to embodiments, after cap oxide layer 404 may be formed, oxide layer 402 may not be directly polished, but polished by polishing cap oxide layer 404. It may be therefore possible to reduce stress applied to oxide layer 402.

Referring to FIG. 4B, oxide layer 402 and polished cap oxide layer 404 may be selectively etched through photolithography and etch processes, thus forming contact hole 406. A barrier metal layer 408 may be deposited on cap oxide layer 404 including contact hole 406. According to embodiments, barrier metal layer 408 may be formed by consecutively depositing Ti and TiN.

Referring to FIG. 4C, a metal layer, for example, a Ti layer, may be deposited on barrier metal layer 408 and may gap fill contact hole 406. The Ti layer and barrier metal layer 408 over cap oxide layer 404 may be sequentially polished to form tungsten plug 406a within contact hole 406.

Referring to FIG. 4D, a metal layer may be deposited on the resulting surface by a CVD method. The metal layer may include aluminum (Al). Ti and TiN may be consecutively deposited on or below the Al layer.

The Al metal layer may be selectively patterned through photolithography and etch processes, thus forming metal wiring 410 electrically connected to semiconductor substrate 400 through tungsten plug 406a.

According to embodiments, after oxide layer 402 for PMD layer are formed through control of HF power, cap oxide layer 404 may be formed and may be polished, for example by a CMP process, and a metal wiring formation process may be performed as described in Table 1. Accordingly, it may be seen that circle defects due to PMD layer may be reduced significantly as in Table 2.

TABLE 2

| | Total | | | Unclassified |
|---|---|---|---|---|
| | Defects | Circle Defects | Minor Defects | Defects |
| Process | 78 | 26 | 22 | 30 |
| condition 1 | | | | |
| Process | 41 | 10 | 27 | 4 |
| condition 2 | | | | |
| Process of | 45 | 8 | 26 | 11 |
| FIG. 4 | | | | |
| Related art | 116 | 49 | 44 | 23 |
| Process | | | | |

As may be seen from Table 2, a smaller number of circle defects may be generated in the process condition 2 according to embodiments.

According to embodiments, a PMD layer may be formed through control of HF power. Accordingly, the uniformity of PMD layer may be improved, circle defects may be minimized, and a reliability and the yield of semiconductor devices may be improved.

Further, according to embodiments, after an oxide layer for a PMD layer may be formed through controlled HF power, a cap oxide layer may be formed and then polished by a CMP process, thus forming PMD layer. It may be therefore possible to reduce stress applied to the oxide layer for PMD layer. Accordingly, the occurrence of circle defects may be minimized, and the reliability and the yield of semiconductor devices may be improved.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
depositing a pre-metal dielectric layer material over a semiconductor substrate through a chemical vapor deposition (CVD) process employing a high frequency (HF) power in a range from approximately 2550 mW to 2650 mW; and
polishing the material to form a pre-metal dielectric layer.

2. The method of claim 1, wherein the chemical vapor deposition process is performed with the high frequency power of approximately 2600 mW.

3. The method of claim 1, wherein the pre-metal dielectric layer material comprises an oxide layer.

4. The method of claim 3, wherein the pre-metal dielectric layer material comprises a cap oxide layer over the oxide layer, wherein the cap oxide layer comprises tetraethyl orthosilicate (TEOS) having a thickness in a range from approximately 4500 Å to approximately 5500 Å.

5. A method, comprising:
forming an oxide layer over a semiconductor substrate;
forming a cap oxide layer over the oxide layer; and
polishing the cap oxide layer to form a pre-metal dielectric layer comprising the oxide layer and the polished cap oxide layer.

6. The method of claim 5, wherein the oxide layer is formed to have a thickness in a range from approximately 5500 Å to approximately 6500 Å through a chemical vapor deposition (CVD) process.

7. The method of claim 6, wherein the chemical vapor deposition process uses a high frequency power in a range from approximately 2550 mW to 2650 mW.

8. The method of claim 7, wherein the chemical vapor deposition process is performed with the high frequency power of 2600 mW.

9. The method of claim 5, wherein the cap oxide layer comprises tetraethyl orthosilicate (TEOS) and is formed to have a thickness in a range from approximately 4500 Å to approximately 5500 Å.

10. A method, comprising:
forming a pre-metal dielectric (PMD) layer over a semiconductor substrate through a chemical vapor deposition (CVD) process;
selectively etching the pre-metal dielectric layer to form a contact hole and depositing a barrier metal layer over the pre-metal dielectric layer including the contact hole;
forming a contact plug within the contact hole; and
forming a metal wiring over the semiconductor substrate, the metal wiring being electrically connected to the semiconductor substrate through the contact plug.

11. The method of claim 10, wherein forming the PMD layer comprises:
depositing pre-metal dielectric layer material over the semiconductor substrate through the chemical vapor deposition process employing a high frequency (HF) power in a range from approximately 2550 mW to approximately 2650 mW; and
polishing the pre-metal dielectric layer material to form the pre-metal dielectric layer.

12. The method of claim 11, wherein the chemical vapor deposition process is performed with the high frequency power of approximately 2600 mW.

13. The method of claim 11, wherein the pre-metal dielectric layer comprises an oxide layer formed to have a thickness of approximately 5500 Å to 6500 Å and a cap oxide layer over the oxide layer and formed to have a thickness of approximately 4500 Å to approximately 5500 Å.

14. The method of claim 10, wherein forming the PMD layer comprises:
forming an oxide layer over the semiconductor substrate through the chemical vapor deposition process using a high frequency (HF) power in a range of approximately 2550 mW to 2650 mW;
forming a cap oxide layer over the oxide layer; and
polishing the cap oxide layer to form the pre-metal dielectric layer including the oxide layer and the polished cap oxide layer.

15. The method of claim 14, wherein the oxide layer is formed to have a thickness of approximately 5500 Å to 6500 Å and wherein the cap oxide layer is formed to have a thickness of approximately 4500 Å to approximately 5500 Å.

16. A device, comprising:
a pre-metal dielectric (PMD) layer formed over a semiconductor substrate through a chemical vapor deposition (CVD) process;
a contact hole formed by selectively etching the pre-metal dielectric layer;
a barrier metal layer deposited over the pre-metal dielectric layer;
a contact plug formed within the contact hole; and
a metal wiring formed over the semiconductor substrate on which the contact plug is formed and electrically connected to the semiconductor substrate through the contact plug.

17. The device of claim 16, wherein the pre-metal dielectric layer is formed by depositing pre-metal dielectric layer material over the semiconductor substrate through the chemical vapor deposition process using a high frequency (HF) power in a range from about 2550 mW to about 2650 mW and then polishing the pre-metal dielectric layer material.

18. The device of claim 17, wherein the pre-metal dielectric layer comprises:
an oxide layer formed over the semiconductor substrate through the chemical vapor deposition process employing a high frequency (HF) power in a range from approximately 2550 mW to 2650 mW; and
a cap oxide layer formed over the oxide layer and then polished.

19. The device of claim 18, wherein the oxide layer is formed to have a thickness of approximately 5500 Å to 6500 Å and wherein the cap oxide layer is formed to have a thickness of approximately 4500 Å to approximately 5500 Å.

20. The device of claim 19, wherein the chemical vapor deposition process is performed with the high frequency power of approximately 2600 mW.
